(19) United States
(12) Patent Application Publication
(10) Pub. No.: US 2005/0017735 A1
(43) Pub. Date: Jan. 27, 2005

(54) Method of determining water content of a material and measuring apparatus

(76) Inventors: Jacques Cariou, Rouen (FR); Alain Gendron, Roger En Roumo (FR); Estelle Ferrari, Le Thuit Signol (FR)

Correspondence Address: MERCHANT & GOULD PC, P.O. BOX 2903, MINNEAPOLIS, MN, 55402-0903, US

(21) Appl. No.: 10/497,884

(22) PCT Filed: Dec. 4, 2002
(86) PCT No.: PCT/FR02/04170

(30) Foreign Application Priority Data
Dec. 5, 2001 (FR) 01/15698

(51) Int. Cl. G01R 27/04; G01R 27/32

(52) U.S. Cl. 324/640

(57) ABSTRACT

The invention relates to a method of determining the water content (Wᵥ %) of a material (12) by using electromagnetic waves, the method comprising following steps: applying an electromagnetic wave;
measuring the propagation time (T) of a surface electromagnetic wave (26) between two points (10, 28);
calculating the dielectric constant (ε′) of said material (12) from said propagation time (V);
determining the dry mass per unit volume (γ_{d}) of the material (12); and
calculating the water content (Wᵥ %) of said material (12) from said dielectric constant (ε′) and said dry mass per unit volume (γ_{d}).

The invention also provides apparatus enabling said water content (Wᵥ %) to be determined using two antennas (10, 28), means (44) for measuring the transit time (T), and processor means (48).

The present invention relates to a method and to apparatus for determining water content of a material by using electromagnetic waves, in particular for mineral materials or organic mixtures.

For a material that is assumed to be constituted by a mixture of aggregate, air, and water, it is known that the water content Wᵥ % can be measured in the laboratory by taking samples of the material from a work site, and then measuring the dielectric constant ε′ of the material, and in particular using the following formula:

$$\frac{{W}_{V}}{100} = α \sqrt{{ɛ}^{′}} + {βγ}_{d} - α where \{ \begin{matrix} α = \frac{1}{\sqrt{{ɛ}_{water}^{′}} - 1} \\ β = \frac{( 1 + \sqrt{{ɛ}_{g}} )}{{γ}_{s} ( \sqrt{{ɛ}_{water}^{′} - 1} )}\end{matrix}$$

which amounts to

$$\frac{{W}_{V}}{100} = {α}^{′} \sqrt{{ɛ}^{′}} + {β}^{′} {γ}_{d} - {α}^{′}$$

where:
ε_{g}^{′} represents the dielectric constant of the aggregate
ε_{water}^{′} represents the dielectric constant of water, with ε_{water}^{′}=78
γ_{d} represents the dry mass per unit volume of material
γₛ represents the specific mass per unit volume of the aggregate.

The dielectric constant ε′ represents the real part of the relative dielectric constant εᵣ=ε′+jε″.

Thus, using a dielectrometer, for example, it is possible to deduce the water content Wᵥ % of the sampled material.

However, measurements of that kind can generally be performed only in the laboratory. Unfortunately, water content is a characteristic which can be used for checking material, in particular when making layers of roadways, and it is therefore particularly advantageous to be able to determine the water content value of the material directly on site.

A first object of the present invention is to provide a method which makes it possible, preferably continuously, to determine the water content of a material on site.

This object is achieved by the fact that the method comprises the following steps:
applying an electromagnetic wave into said material;
measuring the propagation time of a surface electromagnetic wave between two points in such a manner as to determine the propagation speed of said surface electromagnetic wave in said material;
calculating the dielectric constant of said material from said propagation speed;
determining the dry mass per unit volume of the material; and
calculating the water content of said material on the basis of said dielectric constant and of said dry mass per unit volume.

While a wave is being transmitted through the material, the wave follows different paths. The wave can either be reflected directly back to the emitter, or it can be reflected at an interface with some other material, or it can propagate along the surface. This latter type of propagation gives rise to waves that are referred to as “surface” waves.

The real part ε′ of the relative dielectric constant εᵣ, referred to throughout below as the “dielectric constant”, is associated with the propagation speed V of electromagnetic waves in the material by the following relationship:

$$V = \frac{c}{\sqrt{{ɛ}^{′}}}$$

(where c is the speed of light in air)

Although the dielectric constant ε_{water}^{′} of water is large (seventy-eight at 25° C., the dielectric constant ε′ of dry materials hardly ever strays beyond the range two to six for the materials that are the most common. As a result, in a water-and-material mixture, the contribution of water predominates.

Thus, by measuring the propagation time of a surface wave in the material between two points, it is possible to deduce its speed, and given knowledge of the characteristics of the aggregate (ε′_{g} and γ_{g}) and the measured dry mass per unit volume of the aggregate, it is possible to determine the water content of the material.

Advantageously, the various steps of propagating said wave, of measuring said propagation time, and of calculating said dielectric constant are performed continuously so as to determine, continuously, the water content of said material.

In order to make it easier to implement the method continuously, it is preferable to deduce the origin of the detection times of the signals reflected by both antennas. This makes it possible to perform the measurement by means of the constant separation between the two antennas.

In order to counter lack of knowledge about the real time origin, it is advantageous to measure the propagation time by varying different spacings between said points. It is preferable to perform three propagation time measurements, selecting three different spacings between pairs of measurement points.

Advantageously, for the type of checking that is intended, the spacing between the points lies in the range 30 centimeters (cm) to 60 cm, and the passband of the electromagnetic wave lies in the range 200 megahertz (MHz) to 1.2 gigahertz (GHz).

This configuration makes it possible without ambiguity to detect the surface wave which, for the selected frequency band, generally propagates in the first ten centimeters beneath the surface, and to distinguish it from a wave reflected at an interface between two layers of materials of different natures, for example. Frequencies below 200 MHz could be envisaged for performing analyses deeper beneath the surface.

In a second aspect, the present invention provides a device making it possible to determine, preferably continuously, the water content directly on a work site.

This object is achieved by the fact that the apparatus comprises:
an emitter antenna disposed at the surface of said material to apply an electromagnetic wave into said material;
a receiver antenna disposed at the surface of said material and spaced apart from said emitter antenna at a separation distance, and serving to pick up a surface electromagnetic wave;
means for determining the dry mass per unit volume of said material;
means for measuring the transit time of said surface electromagnetic wave through said material between said emitter antenna and said receiver antenna; and
processor means for determining the water content of said material on the basis of said transit time and of said dry mass per unit volume of said material.

The emission of an electromagnetic wave from an emitter antenna placed directly on the surface of the material for analysis gives rise to a plurality of waves propagating within the material for analysis and that can be picked up on the surface. In particular, a surface wave will propagate in the material flush with the surface and will be picked up by a receiver antenna placed on the surface of the material.

Consequently, the method and the measurement technique do not require samples to be taken for analysis in the laboratory, and they make it possible in particular to test directly and continuously on site.

Means for processing the transit time make it possible to deduce the dielectric constant ε′ of material.

Means for processing the dielectric constant ε′ of the material and the dry mass per unit volume of the material enable its water content Wᵥ % to be determined.

Given that the electromagnetic waves emitted by the emitter antenna also propagate in air, they can be picked up by the receiver antenna even without transmitting through the material. Receiving such waves naturally disturbs processing the transit time and thus determining water content.

To eliminate any reception of these “interfering” electromagnetic waves, the emitter and receiver antennas are advantageously each covered in shielding and/or in an absorbent material advantageously filled with graphite.

When only the surface wave is of interest, in order to ensure that it is the propagation time of the surface wave that is measured and not that of a reflected wave, the apparatus may further comprise a separator plate disposed between said emitter and receiver antennas.

Depending on the depth to which the plate is pushed into the material for analysis, the surface wave is no longer picked up. It is therefore possible to distinguish without error between receiving reflected waves and receiving surface-waves, by using transit time measuring means that include a network analyzer.

In order to obtain a passband of 200 MHz to 1.2 GHz, it is advantageous for the emitter and receiver antennas to be selected from antennas that are centered on 500 MHz.

The apparatus is particularly advantageous for continuous inspection, e.g. for a material being made in a fabrication unit, or while laying roadway layers. Under such circumstances, it is preferable for there to be relative movement between the measuring apparatus and the material for analysis. In the first above-mentioned example, the material preferably travels on a conveyor belt past antennas that are stationary, while in the second above-mentioned example, the apparatus is advantageously located on a vehicle that is towed, preferably travelling at the same speed as the material that is in the process of being made, i.e. a speed in the range about 3 kilometers per hour (km/h) to 5 km/h.

Thus, advantageously, relative displacement is implemented between the material and the emitter and receiver antennas, so as to perform measurements continuously.

Nevertheless, when performing static measurements, the emitter and receiver antennas can also be pushed directly into the ground for analysis.

The invention will be well understood and its advantages will appear better on reading the following detailed description of an embodiment given by way of non-limiting example.

The description refers to the accompanying drawing, in which:

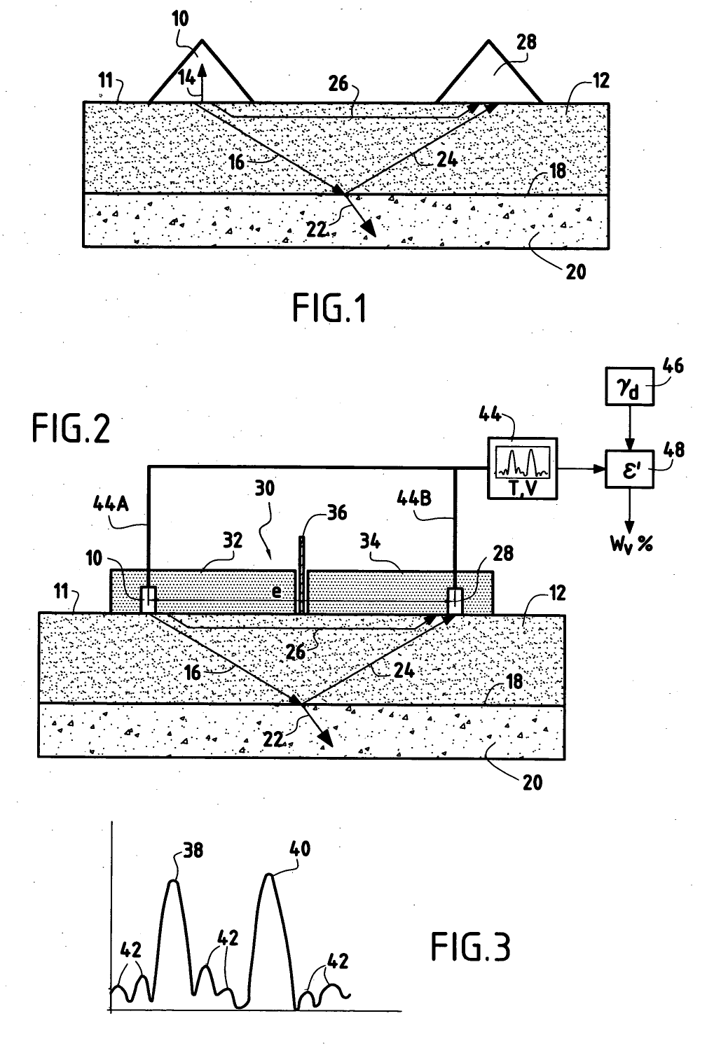

FIG. 1 is a section view of a simplified device showing the various paths followed by a wave being transmitted through a material;

FIG. 2 is a section view of experimental apparatus in accordance with the invention; and

FIG. 3 is a graph showing the signals transmitted through the material into which electromagnetic waves have been sent.

FIG. 1 is a simplified diagram showing the various paths that can be followed by an electromagnetic wave while it is being transmitted from an emitter antenna 10 placed on the surface 11 of a material 12 for analysis. Transmission through air is not shown. The emitted electromagnetic waves preferably have a passband lying in the range 200 MHz to 1.2 GHz.

The electromagnetic wave penetrating into the material 12 can be reflected directly by the material 12 back towards the emitter antenna 10 following the shortest path 14, or on the contrary it can penetrate into the depth of the material 12 along a path 16. When the material 12 presents an interface 18 with a material 20 of different nature, the wave both penetrates into the material 20 along a path 22 and is also reflected at the interface towards the surface along a path 24.

A final possible propagation mode for the wave emitted by the antenna 10 gives rise to a so-called “surface” wave 26. This surface wave 26 follows a path 26 that is substantially parallel to the surface 11 and remains immediately beneath the surface in the material 12.

All of these waves, and in particular the reflected waves 24 and the surface waves 26 can be picked up by a receiver antenna 28 placed on the surface 11 of the material 12.

The apparatus 30 shown in FIG. 2 serves to determine water content, being sure to distinguish receiving a surface wave 26 from receiving a reflected wave 24.

The emitter antenna 10 and the receiver antenna 28 are both placed on the surface 11 of the material 12 for analysis and they are spaced apart from each other a separation distance e. This separation distance e lies in the range 30 cm to 60 cm, and is preferably equal to 45 cm so as to avoid excessive attenuation of the surface wave 26.

The antennas 10 and 28 have respective center frequencies of 500 MHz, and each of them is covered in shielding constituted by a respective absorbent foam 32, 34 that is filled with graphite. The foam 32, 34 serves to avoid emitting/receiving waves that pass from the emitter antenna 10 through the air, by preventing any coupling between the two antennas 10 and 28 via the air, and also protects them from interfering reflections in the environment. Thus, the receiver antenna 28 picks up only waves that have penetrated into the material 12.

As explained in greater detail below, a separator plate 36 is placed between the two antennas 10 and 28 and serves to reveal the surface wave 26. The signal transmitted through the material 12 comprises both surface waves 26 and reflected waves 24 (when these exist, particularly where there is an interface 18 with a material 20 of different composition, for example).

FIG. 3 shows the amplitude of the time signal as recorded by a network analyzer (not shown), for example. A first peak 38 is observed that corresponds to the surface wave 26 and a second peak 40 is observed that corresponds to the reflected wave 24. Lobes 42 can also be seen in this spectrum on either side of the two peaks 38 and 40. These lobes 42 correspond to secondary lobes.

The surface wave 26 is indeed represented by the first peak 38 that appears, since the path followed by said surface wave 26 is shorter than the path followed by the reflected wave 24.

When in doubt as to how to interpret the spectrum, in particular when the first peak 38 does not present an amplitude that is significantly different from that of the second peak 40, as is the case shown in FIG. 3, it suffices to cause the separator plate 36 (FIG. 2) to penetrate far enough into the material 12 to cause the surface wave 26 to disappear since it can no longer propagate to the receiver antenna 28, thereby causing the corresponding peak 38 to disappear from the spectrum. It suffices to identify which peak has disappeared, since that is the peak which corresponds to the surface wave 26, and then to repeat the experiment by raising the separator plate 36 so as to cause the peak corresponding to the surface wave 26 to reappear since the surface wave can again propagate through the material 12.

Means 44 for measuring the transit time of the surface wave 26 comprise emitter means 44A connected to the emitter antenna 10, and receiver means 44B connected to the receiver antenna 28. By way of example, the measurement means 44 comprise such a network analyzer, or else an analog system.

In the absence of complete knowledge concerning the time origin, or the locations of the emission and reception points, the measurement of the transit time T of the surface wave 26 is repeated several times over, preferably three times, with the antennas 10 and 28 being at different separation distances e. Under such circumstances, there is no continuous measurement of water content.

The use of a network analysis makes it possible to display simultaneously the signal transmitted through the material 12 together with the reflection at each of the antennas 10 and 28. In this way, it is possible to perform measurement continuously.

These various different transit times T of the surface wave 26 as a function of the separation distance e between the antennas 10 and 28 make it possible to determine the dielectric constant ε′ of material 12 for analysis by using the following formula:

$$V = \frac{e}{T} = \frac{c}{\sqrt{{ɛ}^{′}}}$$

The means 46 also make it possible to determine the dry mass per unit volume γ_{d} of the material 12, preferably by checking by using gamma ray measurement that gives the wet mass per unit volume γₕ and then using the following formula:

$${γ}_{d} = \frac{1}{1 + {W}_{p} \%} {γ}_{h}$$

where Wₚ % represents the dry mass per unit volume of the material.

Laboratory tests performed on samples of a variety of materials (silica sand, loam, silica gravel, limestone gravel, etc.) have enabled a dielectric constant ε′_{g} to be determined for aggregates and an aggregate specific mass γₛ that are common to these materials. Thus, by selecting 3.72 as the value of the dielectric constant ε′_{g} and 2.66 as the value of the specific mass φₛ, the water content of the material 12 is preferably determined using the following formula:
Wᵥ %=α\sqrt{ε′}−β·γ_{d}−ε

$$where \{ \begin{matrix} α = 12.768 \\ β = 4.458 as determined in the laboratory \\ δ = 12.768\end{matrix}$$

i.e. Wᵥ %=12.768\sqrt{ε′}−4.458γ_{d}−12.769

The two formulas mentioned above are implemented in processor means 48 for determining directly on site the water content Wᵥ % of the material 12 on the basis of the dielectric constant ε′ function of the propagation speed V of the surface wave 26) and of the dry mass per unit volume γ_{d} of the material 12.

Thus, by continuously calculating the real part of the constant ε′ of the dielectric constant and the dry mass per unit volume of the material constituting a roadway for analysis, for example, it is possible to obtain directly on site the water content Wᵥ % of the roadway.

In addition, since Wᵥ %=f (ε′γ_{d}), it follows that this method and this apparatus are particularly well adapted to civil engineering materials for which variation in water content is closely associated with variation in the dielectric constant ε′.

1. A method of determining the water content of a material by using electromagnetic waves, the method being wherein it comprises the following steps:
applying an electromagnetic wave into said material;
measuring the propagation time of a surface electromagnetic wave between two points in such a manner as to determine the propagation speed of said surface electromagnetic wave in said material;
calculating the dielectric constant of said material from said propagation speed;
determining the dry mass per unit volume of the material; and
calculating the water content of said material on the basis of said dielectric constant and of said dry mass per unit volume.

2. A method according to claim 1, wherein the various steps of propagating said wave, of measuring said propagation time, and of calculating said dielectric constant are performed continuously so as to determine, continuously, the water content of said material.

3. A method according to claim 1, wherein said propagation time is measured by selecting different separation distances (e) between said points.

4. A method according to claim 1, wherein the separation distance between said points lies in the range 30 cm to 60 cm.

5. A method according to claim 1, wherein the passband of said electromagnetic wave lies in the range 200 MHz to 1.2 GHz.

6. Apparatus for determining the water content of a material by using electromagnetic waves, the apparatus being wherein it comprises:
an emitter antenna disposed at the surface of said material to apply an electromagnetic wave into said material;
a receiver antenna disposed at the surface of said material and spaced apart from said emitter antenna at a separation distance, and serving to pick up a surface electromagnetic wave;
means for determining the dry mass per unit volume of said material;
means for measuring the transit time of said surface electromagnetic wave through said material between said emitter antenna and said receiver antenna; and
processor means for determining the water content of said material on the basis of said transit time and of said dry mass per unit volume of said material.

7. Apparatus according to claim 6, wherein said emitter and receiver antennas are each covered in shielding.

8. Apparatus according to claim 6, wherein said emitter and receiver antennas are each covered in an absorbent material.

9. Apparatus according to claim 7, wherein said absorbent material is filled with graphite.

10. Apparatus according to claim 6, wherein it further comprises a separator plate disposed between said emitter and receiver antennas.

11. Apparatus according to claim 6, wherein said emitter and receiver antennas are 500 MHz antennas.

12. Apparatus according to claim 6, wherein relative displacement is implemented between said material and said emitter and receiver antennas, so as to perform measurements continuously.
